(19) United States
(12) Patent Application Publication
(10) Pub. No.: US 2009/0079057 A1
(43) Pub. Date: Mar. 26, 2009

(54) INTEGRATED CIRCUIT DEVICE

(75) Inventors: Manfred Mengel, Bad Abbach (DE); Markus Brunnbauer, Lappersdorf (DE); Thorsten Meyer, Regensburg (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Infineon Technologies AG, Neubiberg (DE)

(21) Appl. No.: 11/859,898

(22) Filed: Sep. 24, 2007

(51) Int. Cl. H01L 23/48; H01L 21/56

(52) U.S. Cl. 257/691; 438/107; 257/E23.01; 257/E21.502

(57) ABSTRACT

An integrated circuit device includes a carrier defining a surface with a semiconductor chip including an integrated circuit attached to the carrier. An insulation layer is disposed over the carrier, extending above the surface of the carrier a first distance at a first location and a second distance at a second location. A transition area is defined between the first and second locations, wherein the transition area defines a non-right angle relative to the surface.

### BACKGROUND

Semiconductor devices, such as integrated circuit (IC) packages, typically include one or more semiconductor devices arranged on a lead frame or carrier. The semiconductor device is attached to the lead frame, typically by an adhesive die attach material or by soldering, and bond wires are attached to bond pads on the semiconductor devices and to lead fingers on the carrier to provide electrical interconnections between the various semiconductor devices and/or between a semiconductor device and the carrier. The device is then encapsulated in a plastic housing, for instance, to provide protection and form a housing from which the leads extend.

With such semiconductor packages, especially power semiconductor components, it is desirable to provide high current load-carrying capacity. To this end, some solutions for providing the desired connection density or current capacity require an insulation layer to avoid electrical contact between the conductive connections and the semiconductor device/carrier. Attachment of such an isolation layer in a semiconductor package can be problematic due to factors such as the chip topography, chip positions and geometrical dimensions, the required signal routing the chip to outside connections, etc. In particular, a minimum distance of the isolation material must be kept in the area of the chip edge to maintain necessary electrical isolation of the active area of the chip relative to the conductive strips. lamination process—using lamination film/tape, but adhesion problems and covers underlying topography—tape is put down with pressure, but under topography isn't smooth/flat, can damage chip during lamination process due to pressure applied. Edges of chip, between chip and carrier location is problem with air being trapped due to sharp corner. Accordingly liquid works better, such as spin-on process to apply insulation layer. However, not surface conformal coating—can't get 3D structure.

For these and other reasons, there is a need for the present invention.

### SUMMARY

In accordance with aspects of the present disclosure, an integrated circuit device includes a carrier defining a surface with a semiconductor chip including an integrated circuit attached to the carrier. An insulation layer is disposed over the carrier, extending above the surface of the carrier a first distance at a first location and a second distance at a second location. A transition area is defined between the first and second locations, wherein the transition area defines a non-right angle relative to the surface.

### BRIEF DESCRIPTION OF THE DRAWINGS

Embodiments of the invention are better understood with reference to the following drawings. The elements of the drawings are not necessarily to scale relative to each other. Like reference numerals designate corresponding similar parts.

FIG. 1 is a section view conceptually illustrating an integrated circuit device in accordance with embodiments of the present invention.

FIG. 2 is a close-up view showing portions of the device illustrated in FIG. 1.

FIG. 3 is a flow diagram illustrating a process in accordance with embodiments of the present invention.

FIG. 4 conceptually illustrates aspects of a gray scale lithography process in accordance with embodiments of the present invention.

FIG. 5 is a block diagram conceptually illustrating a top view of a multi-chip module in accordance with embodiments of the present invention.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

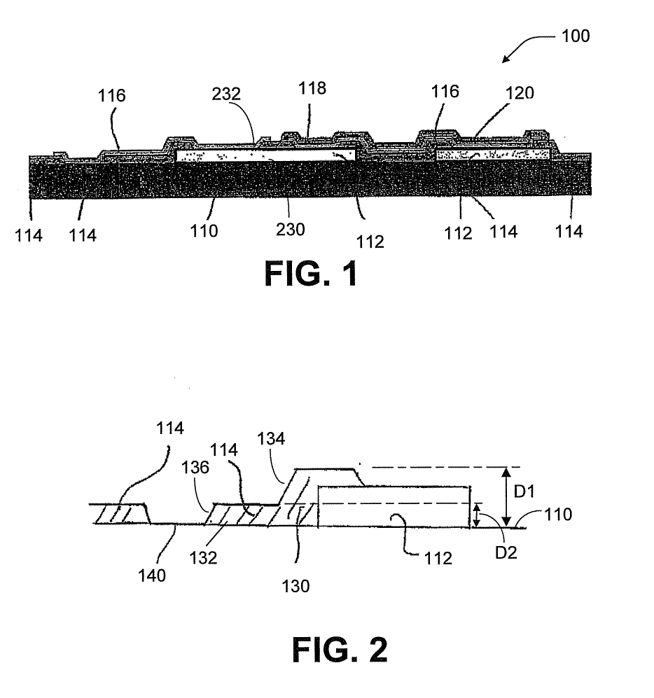

FIG. 1 illustrates a cross-sectional view of one embodiment of an integrated circuit semiconductor device 100. The illustrated device 100 includes a lead frame or carrier 110, with one or more semiconductor chips 112 mounted on the carrier 110. The chip 112, which includes an integrated circuit in exemplary embodiments, can be mounted to the carrier in any suitable manner, such as by soldering or an adhesive.

A first insulation layer 114 is disposed over the carrier 110 and chip 112 such that the first insulation layer 114 extends above the top surface of the carrier 110. A conductive layer 116 is deposited over the first insulation layer 114. The conductive layer 116 includes conductive lines that interconnect the chips 112, or provide interconnections between contact areas of the chips 112 and portions of the carrier 110. A second insulation layer 118 is deposited over the conductive layer 116.

Thus, as illustrated in FIG. 1, the device 100 defines a topography 120 that varies as a result of the various layers and devices deposited on the carrier 100. Thus, the distance that the insulation layer 114 extends above the carrier 110 varies from one location to another. FIG. 2 is a close-up view illustrating a portion of the device 100 (the conductive and second insulation layers 116, 118 are not illustrated in FIG. 2 for sake of clarity). At a first location 130, a portion of the insulation layer 114 is deposited over the chip 112 and thus extends a first distance D1 above the carrier 110. At a second location 132 the insulation layer extends 114 is deposited only on the carrier 110 and thus extends a second distance D2 above the carrier 110. A transition area 134 is defined between the first and second locations 130, 132.

As illustrated in FIG. 2, the vertical edges of the chip 112 are perpendicular to the top surface of the chip 110. Rather than mirror the right angle defined between the edge of the chip 112 and the horizontal surface of the carrier 110, the transition are defines a non-right angle. In other words, the transition area 134 is not perpendicular to the top surface of the carrier 110. For example, the transition area 134 may define an angle of less than 80 degrees and greater than 10 degrees in certain embodiments. Having such a “ramped” transition area 134 facilitates the deposited conductive lines that replace conventional wire bonds.

Further, the first isolation layer 114 defines a through hole 140, which would typically positioned over a contact area of the chip or carrier to facilitate an electrical connection of the conductive layer to such a contact area. As shown in FIG. 2, the sidewall of the through hole 140 defines a transition 136 area between the surface of the carrier 110 and the second distance D2 of the insulation layer 114 above the carrier 110. As with the first transition area 134, the sidewall, or transition 136 is not perpendicular to the top surface of the carrier 110, but rather defines a ramped surface.

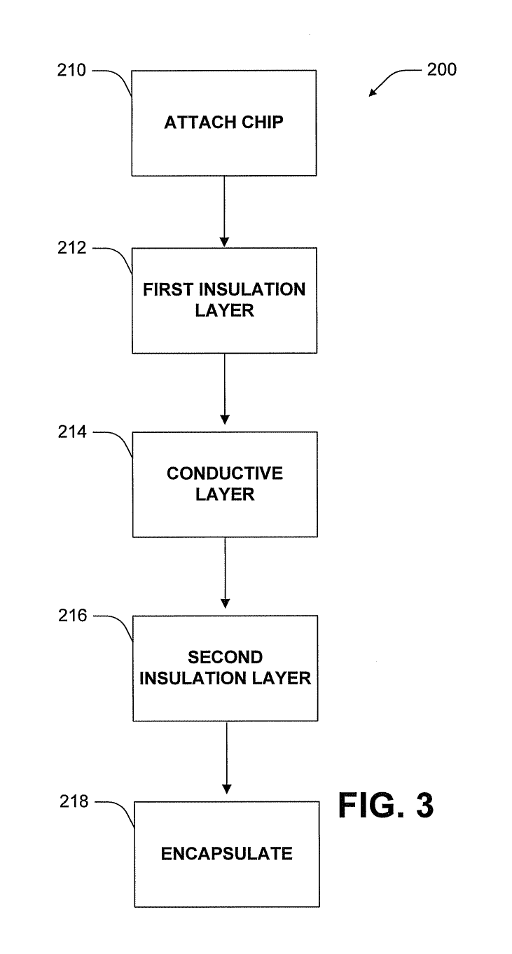

FIG. 3 is a flow diagram generally illustrating an exemplary process 200 for manufacturing an integrated circuit such as the device 100 in accordance with aspects of the present invention. In box 210, the chip 112 is attached to the carrier 110 by any suitable method, such as soldering or via an adhesive. In box 212, the first insulation layer 114 is applied to the carrier and chip as necessary, leaving certain areas open such as the through hole 140. The conductive layer 116 is deposited over the first insulation layer 114 in box 214, and the second insulation layer 118 is deposited in box 216. In box 218, the device 100 is encapsulated, for example, by any suitable molding process.

As illustrated in FIGS. 1 and 2, the insulation layers 114 and 118 include ramped transition areas 134 and 136, avoiding sharp comers where the first insulation layer 114 changes due to changes in the topography of the device 100. In certain exemplary embodiments, a photolithography process is used to achieve the ramped transition areas. More specifically, a gray scale lithography process is used in some embodiments to achieve the desired 3D structure of the insulation layers.

With conventional processes, dry anisotropic etching process would typically be used to pattern the insulation layer, resulting in transition areas defining vertical sidewalls (perpendicular to the top surface of the carrier 110). In accordance with aspects of the present invention, gray scale lithography is used to create ramped transition areas. With the gray scale lithography process, the exposure dose is varied to develop the 3D structure in the resist layer. Differential exposure doses result in a corresponding differential depth of the exposed resist across the surface due to the photoactive compound absorbing ultraviolet light energy as it travels in the depth of the resist layer. By using chrome-on-glass (COG) masks that induce diffraction, the ultraviolet intensity can be modulated. In exemplary processes, the COG mask is patterned with opaque pixels where both the size and the pitch of the pixels are close to or below the resolution of the given lithography system to achieve the desired diffraction.

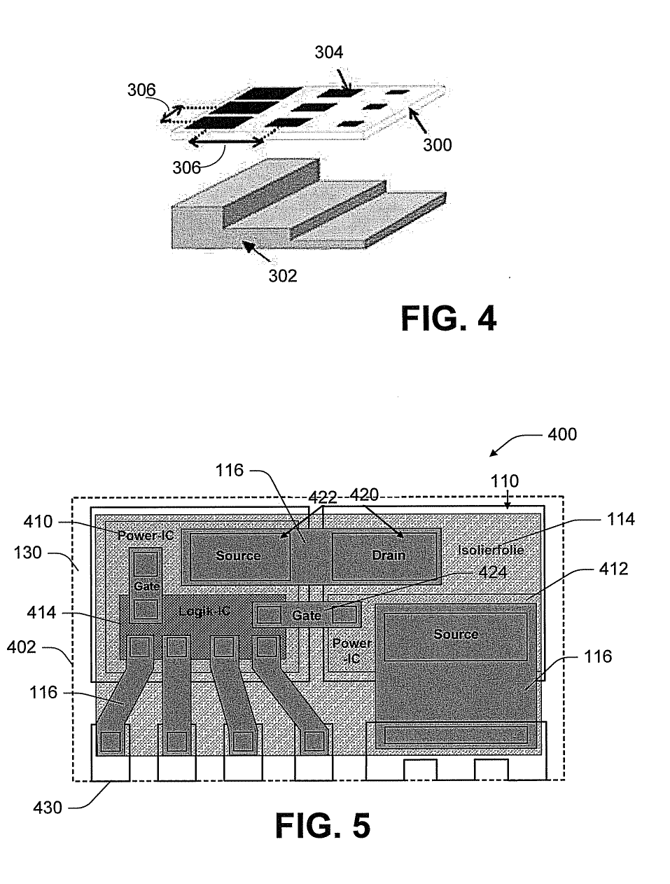

FIG. 4 illustrates a mask 300 and a photoresist 302. The exemplary mask 300 includes square pixels 304 and a set pitch 306 between the pixels 304. The intensity depends on the percentage of the opaque area for each pitch area. In this case the pitch 306 is chosen to be below the resolution of the projection system so that the distance between each pixel 304 remains below the resolution. The pixel size can be modified to modulate vary the intensity passing through the objective lens. Another method to change the intensity is to keep the size of the pixel constant and change only the pitch, or it is possible to change both the size and the pitch.

Alternative embodiments are envisioned in which the insulation layers 114, 118 are formed using a laser ablation process, in which the insulation layer material is selectively removed by irradiating it with a laser beam to achieve the ramped or angled transition areas 134, 136. With such a process, the amount of material removed can be adjusted by varying the moving speed of the laser and/or the temperature of the laser, for example.

As noted above, the ramped transition areas facilitate the use of conductive lines deposited over the insulation layer, rather than using traditional bond wires for interconnecting chips and/or providing connections between chips and the carrier. The ramped transition areas further facilitate the use of such deposited conductive lines for connecting the backside of a flip-chip mounted chip to a carrier, such as for a device having a drain terminal on one side of the chip and source/gate terminals on an opposite side. For example, referring to FIG. 1, the chip 112 can include a first, or front side 230 that is electrically connected to the carrier 110 such as by an array of interconnect solder balls. A second, or back side 230, is electrically connected to the carrier 110 via the conductive layer 116 deposited over the first insulation layer 114.

FIG. 5 illustrates an exemplary multi-chip module 400 in accordance with embodiments of the invention. The multi-chip module 400 includes semiconductor chips situated on a carrier 110. An insulation layer 114 is deposited over the semiconductor chips and the carrier 110, and the multi-chip module 300 is surrounded by an encapsulation 402.

The semiconductor devices include first and second power transistors 410,412 mounted on the carrier 110. A logic device 214 is mounted on the power transistor 410. Alternatively, the logic device 414 can be arranged along side the power transistors 410,412 if space allows. The power transistors 410,412 are arranged in a half bridge configuration, with the drain connection 420 of the high side device 412 connected to the source 422 of the low side device 410 by conductive lines 116 deposited on the insulation layer 114. In accordance with the disclosure above in conjunction with FIGS. 1-4, the insulation layer 114 defines ramped transition areas between locations of the insulation layer 114 defining varying distances above the carrier 110. Among other things, such transition areas facilitate the deposition of the conductive lines 116.

The logic device 414 is connected for controlling the power transistors 410,412 via their gate contacts 424. Conductive connections 116 are further situated between various terminals of the semiconductor devices and contacts 430 situated at the periphery of the package 400, with the insulation layer 114 situated between the chips/carrier and the deposited conductive connections 116. In some embodiments, a second insulation layer is deposited over the conductive layer. The configuration shown can be extended the addition of further semiconductor components as well as passive elements, for example.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit device, comprising:
a carrier defining a surface;
a semiconductor chip including an integrated circuit attached to the carrier;
an insulation layer disposed over the carrier, the insulation layer extending above the surface of the carrier a first distance at a first location and a second distance at a second location with a transition area defined between the first and second locations, wherein the transition area defines a non-right angle relative to the surface.

2. The integrated circuit device of claim 1, further comprising a conducting line disposed over the insulation layer.

3. The integrated circuit device of claim 2, wherein the conducting line is electrically connected to the semiconductor chip.

4. The integrated circuit device of claim 1, further comprising a plurality of semiconductor chips attached to the carrier.

5. The integrated circuit device of claim 1, wherein the transition area defines an angle of less than 80 degrees relative to the surface of the carrier.

6. The integrated circuit device of claim 1, wherein the transition area defines an angle of greater than 10 degrees relative to the surface of the carrier.

7. The integrated circuit device of claim 2, further comprising a second insulation layer deposited over the conductive layer.

8. The integrated circuit device of claim 1, wherein the transition area is the side wall of a through hold defined by the insulation layer.

9. The integrated circuit device of claim 2, wherein the chip defines a first side and a second opposite the first side, wherein the first side is situated adjacent the carrier and electrically connected to the carrier, and wherein the second side is electrically connected to the carrier via the conducting line disposed over the first insulation layer.

10. A method for producing an integrated circuit device, comprising:
providing a carrier;
attaching a semiconductor chip to the carrier;
depositing a first insulation layer on the carrier and semiconductor chip, where the first insulation layer extends above a surface of the carrier a first distance at a first location and a second distance at a second location; and
patterning the first isolation layer to define a transition area between the first and second locations, wherein the transition area defines a non-right angle relative to the surface of the carrier.

11. The method of claim 10, further comprising depositing a conductive layer over the first insulation layer.

12. The method of claim 11, further comprising depositing a second insulation layer over the conductive layer.

13. The method of claim 10, further comprising attaching a plurality of chips to the carrier.

14. The method of claim 10, further comprising forming a through hole in the first insulation layer, wherein the transition area is a sidewall of the through hole.

15. The method of claim 10, wherein forming the first insulation layer includes a gray scale lithography process.

16. The method of claim 10, wherein forming the first insulation layer includes a laser ablation process.

17. The method of claim 11, further comprising electrically connecting first and second opposing sides of the chip to the carrier, wherein the second side is electrically connected by the conductive layer.
